(19) United States
(12) Patent Application Publication
(10) Pub. No.: US 2019/0222211 A1
(43) Pub. Date: Jul. 18, 2019

(54) SWITCHING POWER MODULE COMBINING A GATE DRIVER WITH A PHOTONIC ISOLATED POWER SOURCE

(71) Applicant: MH GoPower Company Limited, Kaohsiung Coty (TW)

(72) Inventors: Mei-huan Yang, Kaohsiung City (TW); Cheng-liang Wu, Kaohsiung City (TW); Remigio Perales, Oberlin, OH (US); Kun-hsien Chen, Kaohsiung City (TW); Wei-sheng Chao, Kaohsiung City (TW); Ying-lin Tseng, Kaohsiung City (TW); I-tsung Chen, Tainan City (TW)

(21) Appl. No.: 16/246,855

(22) Filed: Jan. 14, 2019

Related U.S. Application Data
(60) Provisional application No. 62/713,070, filed on Aug. 1, 2018.
(60) Provisional application No. 62/617,248, filed on Jan. 14, 2018.

(51) Int. Cl. H03K 17/785; H01L 31/0687; H03K 17/78; H01L 31/16; H05K 1/18; H05K 1/14

(52) U.S. Cl. CPC H03K 17/785; H01L 31/0687; H03K 17/78; H01L 31/16; H05K 1/181; H05K 2201/10522; H05K 2201/10015; H05K 2201/10174; H05K 2201/10106; H05K 2201/10121; H05K 2201/10545; H05K 1/144

(57) ABSTRACT

This disclosure presents a power switching module combining a novel gate driver with a photonic isolated power source which can output a high voltage and high power at the same time, and thus can drive a power semiconductor device. The disclosed power switching module could simplify the switched mode power supply structure to (1) replace the isolated power supply module; (2) simplify circuitry of the gate driver by integrating gate driver signaling opto-electronics; and (3) provide a module with power semiconductor device under switched mode power supply structure.

### CROSS-REFERENCE TO RELATED APPLICATIONS

This application claims priority to U.S. Provisional Application Ser. No. 62/617,248 filed on Jan. 14, 2018, entitled “SWITCHING POWER MODULE COMBINING A GATE DRIVER WITH A PHOTONIC ISOLATED POWER SOURCE” and to U.S. Provisional Application Ser. No. 62/713,070 filed on Aug. 8, 2018, entitled “SWITCHING POWER MODULE COMBINING A GATE DRIVER WITH A PHOTONIC ISOLATED POWER SOURCE,” the entireties of which are incorporated herein by reference.

### FIELD

The disclosure relates to a switching power module, more particular to a power driving device capable of delivering control signals and power at the same time, and its circuitry.

### BACKGROUND

Currently, a power semiconductor device (PSD), such as a metal-oxide-semiconductor field effect transistor (MOSFET) or an insulated gate bipolar transistor (IGBT) is driven by a power driving module. Power MOSFETs and IGBTs are simply voltage driven switches, because their insulated gate behaves like a capacitor and no current flows once the voltage level is reached.

In simplified form, a circuit block for powering a power semiconductor device such as MOSFET or the IGBT comprises an isolated power supply module and a gate driver. A MOSFET generally requires a gate driver to perform the on/off operation at the desired frequency. For high frequencies, MOSFETs require a gate drive circuit to translate the on/off signals from an analog or digital controller into the power signals necessary to control the MOSFET. The isolated power supply module is typically an isolation transformer or an isolated converter, which is an electronic power supply that incorporates a switching regulator to convert electrical power efficiently. Like other power supplies, a switch mode power supply (SMPS) transfers power from a DC or AC source (often line power or “wall plug” power) to DC loads, such as a personal computer, while converting voltage and current characteristics. The gate driver accepts a low-power input from a controller and opens or closes the power semiconductor device, such as an IGBT or power MOSFET.

High voltage sources have found a wide range of applications in different areas including charging devices or power semiconductor device modules. High-voltage MOSFETs/IGBTs are commonly used as modules with ratings from 15V to 3,000V and higher, aimed at inverters, converters, power supplies, motor control and traction applications. At least one gate driver is needed to drive the MOSFETs/IGBTs. Particularly, the gate driver for power inverters and converters requires electrical isolation. Typically, an isolation transformer connected to the gate driver is to provide isolated power and voltages for operation of MOSFETs/IGBTs. Thus the MOSFETs/IGBTs can rapidly switch between their operational on and off states in response to the gate driver. In general, the isolation transformer has solid magnetic cores to provide galvanic isolation between circuits. However, this causes an increase in cost because high voltage isolation transformers are typically custom-built. Further, high voltage isolation transformers are heavy and huge in order to obtain the high isolation voltages. For example, typical dimensions of an isolation transformer with an isolation voltage of 20 kV, are 200 mm×200 mm×200 mm at a weight of approximately 5.5 kg.

In another prior art example, a photocoupler can be combined in the gate driver and powered by a power supply. The photocoupler is an opto-electronic device that comprises a light source (light emitter) and a light receiver (light detector) structurally coupled by any of the various types of optic and electric connections. Such devices have advantages due to the use of electrically neutral photons to transmit information. The photocoupler is primarily used for controlling optically guided high-current, high-voltage circuits remotely. The photocoupler can be quite effective in power supplies as a control element that ensures complete isolation for secondary circuits of the power semiconductor device.

U.S. Pat. No. 5,514,996 titled “Photo-coupler apparatus” disclosed a photo-coupler apparatus having a light emitting element in the primary side. The secondary side of this apparatus is comprised of a photoelectromotive diode array, a light sensitive impedance element series-connected to said array, a drive transistor, and at least one output MOSFET connected to the output terminals of this apparatus. The light sensitive impedance element comes into a large impedance state when an optical signal from the light emitting element is weak. In this case, the light sensitive impedance element generates a sufficient voltage to activate the drive transistor, in spite of the photocurrent being small. This results in an improvement of the dynamic sensitivity of this apparatus. When said optical signal is strong, the impedance element comes into a small impedance state, thus providing the MOSFET with a sufficient photo-current. This results in the shortening of switching times of the output MOSFET.

U.S. Pat. No. 7,834,575 titled “Gate-driver IC with HV-isolation, especially hybrid electric vehicle motor drive concept” disclosed an automotive drive system for a high voltage electric motor comprising a microcontroller and ECU powered by a low voltage (12 volt) bus net which controls the drives of a high voltage inverter powered by a 100V or higher source, which, in turn, drives the motor. To provide good electrical insulation between the low voltage and high voltage systems, the low voltage control signals are produced by a low voltage (LV) signal input chip which has a bottom electrode which produces a control potential responsive to the ECU output and a high voltage driver IC which drives the power devices of the high voltage inverter. The high voltage driver IC has a top electrode which drives the high voltage IC function. The bottom electrode of the LV input chip is coupled to the top electrode of the high voltage driver IC through an insulation layer, defining a capacitive coupler which defines an isolation barrier between the low voltage net and the high voltage system insulation. The two ICs may be bare chips, individually packaged chips or co-packed chips. Plural control IC chips and driver IC chips can communicate with one another for diverse control functions, including “smart” functions.

However, the above circuits, which require a gate driver and an isolation transformer are complex in circuit design, space wasting and cost expensive.

Another disadvantage of traditional isolated power supplies is their high isolation capacitance. Isolation capacitance is a measure of the capacitance between isolated components, such as between the low voltage input and the high voltage output of an isolated power supply. The value of the isolation capacitance is an important parameter when selecting components (such as isolated power supplies) and designing the circuitry for gate drivers of PSDs. This is because the capacitance between the input from the low voltage power supply and the output of the isolated power supply impacts the magnitude of transient currents (or electrical noise) seen at the gate of the PSD as well as the value of transient currents seen at the power source of the low voltage control circuitry used to generate and send the on/off signals to the gate driver. The value of this transient current can be expressed as Itc=(Cgd+Cps)*dV/dt where Cps is the isolation capacitance of the isolated power supply, and Cgd is the isolation capacitance of the isolated gate driver. Finally, dV/dt is the change in the value of V_{DS}, i.e. the change in the voltage value between the drain and source of the PSD (a MOSFET in that case), as it switches from on-off state, and vice versa. The noise generated by dV/dt in the circuit is known as common mode noise, and the value of Itc reflects the magnitude of the common mode noise.

High levels of common mode noise can result in interrupting the control circuitry's signaling, disrupting gate driver function. Also, each component in the gate driver is exposed to the common mode noise, and if the common mode transient current (and associated transient voltage) exceeds the rated value for that component, it will fail. Since the value of the common mode transient current (Itc) is a function of dV/dt, faster switching PSDs, such as those based on GaN and SiC materials, switch voltage at faster rates, and therefore generate higher levels of common mode transient currents. This means that failures of the low voltage control circuitry or components utilized within the gate driver are more likely to occur. Therefore, for fast switching speed PSDs, such as GaN and SiC based devices, low isolation capacitance from the power supply is of great value.

### SUMMARY OF THE INVENTION

In a first aspect, there is an integrated power source comprising: a first printed circuit board (PCB); a second PCB; a photonic isolated power source comprising: a light transmitter surface mounted on a first side of the first PCB; and a multijunction photovoltaic (PV) cell surface mounted on a first side of the second PCB and configured to detect light emitted by the light transmitter; a gate driver circuit; and a housing enclosing the first PCB, the second PCB, and the photonic isolated power source, wherein the first side of the first PCB and the first side of the second PCB face each other, and wherein an output of the photonic isolated power source and the gate driver circuit are configured to supply power to and drive at least one downstream power semiconductor.

In an example of aspect 1, the gate driver circuit is enclosed within the housing.

In another example of aspect 1, the at least one downstream power semiconductor is a metal-oxide-semiconductor field effect transistor or an insulated gate bipolar transistor.

In yet another example of aspect 1, the multijunction PV cell is a vertical multijunction (VMJ) PV cell.

In an example of aspect 1, the light emitter and the PV cell are separated by a gap, wherein optical silicone at least partially fills the gap.

In another example of aspect 1, the integrated power source further comprises a heat sink on which the housing is mounted.

In yet another example of aspect 1, the photonic isolated power source or the gate driver circuit is supplied by a switching power supply.

In another example of aspect 1, an output of the gate driver circuit is supplied to the photonic isolated power source and configured to switch the photonic isolated power source.

In yet another example of aspect 1, an output of the photonic isolated power source is supplied to the gate driver circuit, and the gate driver circuit is configured to switch a supply of power from the photonic isolated power source to and drive the at least one downstream power semiconductor.

In an example of aspect 1, the integrated power source further comprises a capacitor and/or a Zener or Schottky diode connected in parallel with the PV cell, wherein the capacitor and/or the Zener or Schottky diode is mounted to a second side of the first PCB or the first side of the second PCB.

In a second aspect, there is an intelligent power module comprising: at least one integrated power source of aspect 1; and at least one downstream power semiconductor, wherein an output of the integrated power source is configured to supply power to and drive the at least one downstream power semiconductor, and wherein the housing further encloses the at least own downstream power semiconductor.

In an example of aspect 2, the at least one integrated power source of aspect 1 includes a high voltage integrated power source and a low voltage integrated power source, the at least one downstream power semiconductor includes a high voltage downstream power semiconductor and a low voltage downstream power semiconductor, the high voltage integrated power source is configured to supply power to and drive the high voltage downstream power semiconductor, and the low voltage integrated power source is configured to supply power to and drive the low voltage downstream power semiconductor.

In another example of aspect 2, the at least one integrated power source of aspect 1 includes a first integrated power source, the at least one downstream power semiconductor includes a high voltage downstream power semiconductor and a low voltage downstream power semiconductor, the high voltage downstream power semiconductor and the low voltage downstream power semiconductor operating at a common phase, and the first integrated power source is configured to supply power to and drive the high voltage downstream power semiconductor and the low voltage downstream power semiconductor.

In yet another example of aspect 2, the at least one integrated power source of aspect 1 includes a first high voltage integrated power source, a second high voltage integrated power source, and a low voltage integrated power source, the at least one downstream power semiconductor includes first and second high voltage downstream power semiconductors and first and second low voltage downstream power semiconductor, the first high voltage integrated power source is configured to supply power to and drive the first high voltage downstream power semiconductor, the second high voltage integrated power source is configured to supply power to and drive the second high voltage downstream power semiconductor, and the low voltage integrated power source is configured to supply power to and drive the first and second low voltage downstream power semiconductors.

In a third aspect, there is an integrated power source comprising: a first printed circuit board (PCB); a second PCB; a photonic isolated power source comprising: a light transmitter surface mounted on a first side of the first PCB; and a multijunction photovoltaic (PV) cell surface mounted on a first side of the second PCB and configured to detect light emitted by the light transmitter; a gate driver circuit; and a housing enclosing the first PCB, the second PCB, the photonic isolated power source, and the gate driver circuit, wherein the first side of the first PCB and the first side of the second PCB face each other and the light emitter and the PV cell are separated by a gap, and wherein an output of the photonic isolated power source and the gate driver circuit are configured to supply power to and drive at least one downstream power semiconductor.

### BRIEF DESCRIPTION OF THE DRAWINGS

FIG. 1 shows an example of a simplified power module structure by using a photonic isolated power source of this disclosure without using an independent isolated power supply.

FIG. 2a shows a cross-sectional schematic diagram of an edge-illuminated vertical multijunction photovoltaic receiver; FIG. 2b shows a PN junction of the edge-illuminated multijunction of FIG. 2a.

FIG. 3 shows a first embodiment of the disclosure, illustrating the photonic isolated power source as part of a simplified circuit driving power semiconductor.

FIG. 4 shows a second embodiment of the disclosure, illustrating the gate driving module in which a gate driver disposed before the photonic isolated power source.

FIG. 5 shows a third embodiment of the disclosure, illustrating a photonic isolated power source and an external controller switched by the end user as part of a switching power circuitry diagram.

FIG. 6 shows another embodiment of the disclosure comprising a photonic isolated power source comprising a photocoupler that includes a light source and a light detector to convert the optical light to electricity.

FIG. 7 illustrates a first packaging embodiment of the disclosure.

FIG. 8 illustrates a second packaging embodiment of the disclosure.

FIG. 9 shows an example electrical schematic integration of a gate driver with a photonic isolated power source, when in the same package.

### DETAILED DESCRIPTION OF THE INVENTION

Relative to traditional isolated power supplies such as isolation transformers or isolated DC-DC converters, photonic isolated power sources offer lower isolation capacitance, helping to reduce the total capacitance of gate driver circuits, thereby reducing the magnitude of common mode transient currents. Conventional techniques for delivering isolated power such as magnetic induction through isolation transformers, or capacitive coupling require conductors in close proximity to each other (the closer together, the better the efficiency), which creates a high isolation capacitance value.

Photonic isolated power sources utilize a light source (such as an LED) to transmit optical power through an insulating medium (such as air) to a PV cell which converts the light to electricity, thus providing isolated power. For photonic isolated power sources, the distance between the light source (low voltage side) and the PV cell (high voltage side) that converts the light to electricity can be easily increased, thus reducing the capacitance value of the isolated power source. In addition, the insulating medium between the light source and the PV cell can be modified, altering the isolation capacitance value. Furthermore, other features such as the PV cell or the LED's (light source) surface area can be adjusted, further impacting the isolation capacitance value. As a result, a photonic isolated power supply provides a very flexible approach to providing a low isolation capacitance.

It has historically been difficult to fabricate reliable, high power density, high voltage density photovoltaic (PV) cells. Driving a power semiconductor gate generally requires both high power density and high voltage density within a compact integrated circuit package. The lack of a high voltage density, high power density PV cells has meant that photonic isolated power supplies have not been able to satisfy these demanding requirements. In view of the foregoing, it is greatly desired to develop a photonic power driving module which may output high voltages and high power to replace the traditional isolated power supply in power modules.

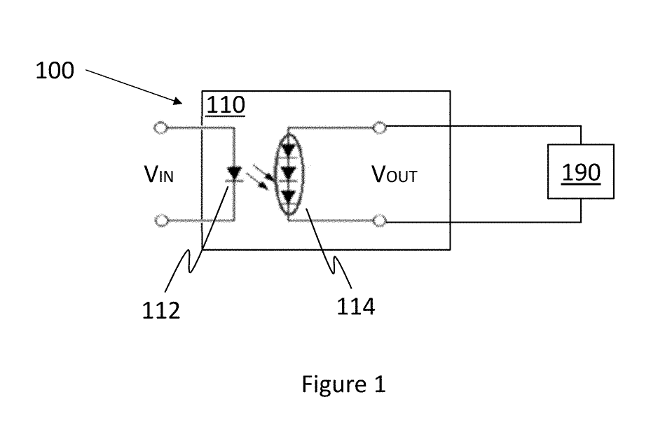

FIG. 1 shows an example of a simplified power module 100 structure by using a photonic isolated power source of this disclosure without using an independent isolated power supply. As used herein, the term “photonic isolated power source” (or photonic isolated power supply) refers to an isolated power source that includes a light transmitter (such as an LED or laser), an insulating medium from which the optical power is transmitted through (such as air), and a light receiver (such as photovoltaic cell) which converts the optical power into electrical power. The photonic isolated power source may include other integrated components, such as a Zener diode and capacitor which together provide useful features for providing power for gate drivers. With reference to FIG. 1, a photonic isolated power source 110 comprises a light transmitter 112, and a light receiver 114. The light transmitter 112 is used for providing a light energy; and the light receiver 114 is used for receiving the light energy to generate a high voltage and high power to drive at least one power semiconductor device 190. As used herein, the term “high voltage” refers to up to approximately 30V, or the highest voltage capable of (needed to) turning on or off the gate of a PSD. As used herein, the term “high power” refers to tens of milliwatts (mW) to watts. In this aspect, the photonic isolated power source 110 serves as a gate driving module that can provide both the switching signal and sufficient power, and can do so with sufficient voltage (an exemplary range is 5V to 30V output) and sufficient current to drive the power semiconductor device 190 (e.g. a MOSFET or an IGBT) with high frequency by using high voltage and high power photovoltaic cells as the light receiver 114. Therefore, the photonic isolated power source 110 serving as the gate driving module could further simplify conventional switched mode power supply structures to (1) replace the isolated power supply module described above; (2) simplify circuitry of the gate driver of prior art aspects by integrating gate driver signaling opto-electronics; and (3) provide a module with a power semiconductor device under a switched mode power supply structure. Namely, the photonic isolated power source 110 of this disclosure can be used to create a power semiconductor device gate driver without using an independent isolated power supply, and thus can be housed in a small package, saving board space and packaging weight. For high power applications, MOSFETs (or other power semiconductor devices) using Si, SiC or GaN substrates can be used.

Furthermore, the light transmitter 112 of the photovoltaic cell can be a high power laser diode (LD) or a high power light emitting diode (LED) or a vertical cavity surface emitting laser (VCSEL). The light receiver 114 in the photonic isolated power supply 100 includes at least a photovoltaic cell which can output a high voltage and high power. The light receiver 114 can be a multijunction (MJ) cell, a vertical multijunction (VMJ) cell, or a vertical epitaxial hetero structure architecture (VEHSA) cell, which may comprise a silicon or III-V semiconductor material.

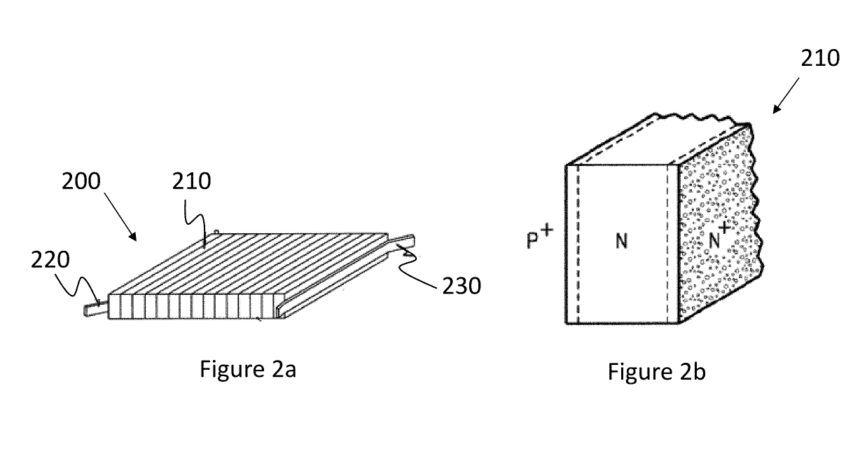

With further reference to FIGS. 2a and 2b, in one embodiment, the light receiver 114 in the photocoupler is a VMJ cell 200, and the light receiver components 210 are cell junctions of the VMJ cell 200 with two end contacts 220, 230. In some embodiments, additional contacts can be included between internal PN junctions, thus providing alternative voltage outputs depending on the set of connected contacts. In these cases, the zero (or ground) voltage may be established at a metal contact in the middle of the cell. The cell junctions 210 can include one or more PN cell junctions, and optionally, any requisite electrodes and wiring. The contacts 220, 230 can be metal contacts comprising any electrically conductive metal, and can be end contacts or internal contacts. FIG. 2a shows a cross-sectional schematic diagram of an edge-illuminated vertical multijunction photovoltaic receiver and FIG. 2b shows one PN junction. The VMJ cell 200 is a high-voltage light receiver which has a small feature size and is light weight, and allows output voltages higher than single junction cells. Typically, a 10 mm×10 mm VMJ cell 200 can generate a voltage of no less than 25V under one sun illumination, whereas conventional single junction cells can only generate a few volts at best. Therefore, generating high voltage and high power outputs is possible for modern VMJ cells.

The multiple junctions of the VMJ cell 200 are stacked such that all the junctions 210 have their positive-charged side facing the same direction. Alternatively, in another embodiment, the multiple junctions 210 of the light receiver may periodically alternate between their positive and negative sides. Between the multiple junctions 210 there may also be one or more metal contacts that separate the junctions. The junctions may be stacked on either side of the metal contact in the same positive/negative orientation, or the junctions may reverse their orientation (polarity) on either side of the metal contact. At each location where a metal contact is placed, the voltage at that contact can be accessed. Metal contacts may be connected to cell junctions, other metal contacts, or other parts of the cell by appropriate wiring, for example. By including metal contacts at different locations within the stack (i.e. having differing numbers of cell junctions between the metal contacts), different voltages will be made available to the circuitry, creating the opportunity for different voltage outputs and both positive and negative voltage outputs, relative to a central ground voltage output of a selected metal contact. This concept is more fully detailed in U.S. application Ser. No. 14/753,515, herein incorporated by reference.

Furthermore, the output of the light receiver 114 can provide a low noise voltage source to achieve high voltage isolation, and the output voltages of the light receiver can be regarded as non-transformer isolated voltages. Therefore, the photonic isolated power source 110 is suitable for replacing an isolation transformer in power module.

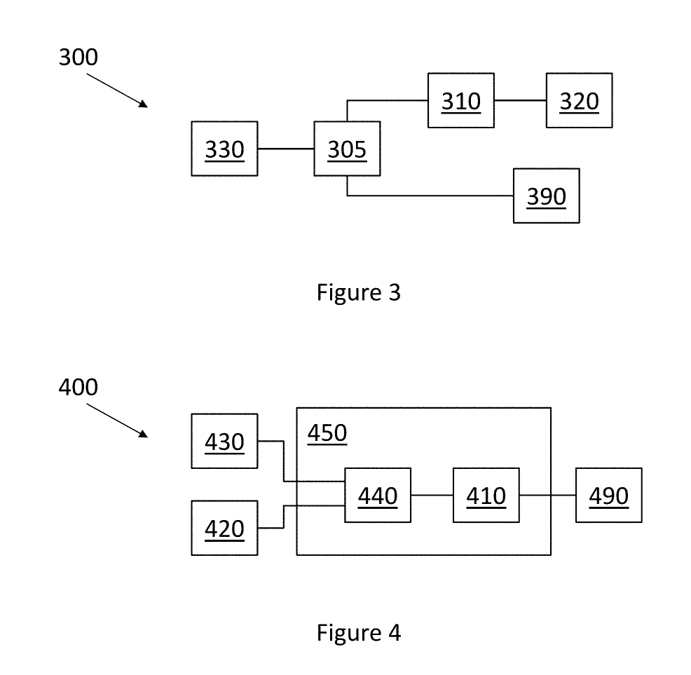

FIG. 3 shows a first embodiment 300 of the present disclosure, illustrating the photonic isolated power source 310 as part of a simplified circuit driving a power semiconductor 390. In this embodiment, a photonic isolated power source 310 is used for driving at least one power semiconductor device 390. The photonic isolated power source 310 comprises a light transmitter and a light receiver, such as that described above with respect to FIG. 1. As discussed therein, the light transmitter is used for providing a light energy; and the light receiver is used for receiving the light energy to generate a high voltage and high power to drive the at least one power semiconductor device 390. The at least one power semiconductor device 390 can be a MOSFET or an IGBT, or any other power semiconductor device that is switchable (other examples include thyristors, FETs, or BJTs). The light receiver of the photonic isolated power source 310 can be a photovoltaic cell as described above. The photonic isolated power source 310 can be packaged in a mounted substrate with a heat sink, such as a cold plate, to achieve heat dissipation. To improve the heat dissipation rate, a thermal interface material can be disposed between the photonic isolated power source 310 and the heat sink. The light source of the photonic isolated power source 310 may be powered by a power source 320 such as a battery or line power/voltage. Additionally, a control signal input 330 may be isolated via a photocoupler 305 (by controlling a light source of the photocoupler 305), the output of which controls a MOSFET (e.g., as part of a grate driving circuit) or like device that controls operation of the power semiconductor device 390.

FIG. 4 shows another embodiment 400 of the disclosure, illustrating a gate driving module 450 with a gate driver 440 disposed before the photonic isolated power source 410. In this embodiment, a gate driving module 450 used for driving at least one downstream power semiconductor device 490 (e.g. a MOSFET or IGBT) comprises a photonic isolated power source 410 and a gate driver 440. As above, the photonic isolated power source may be embodied as a light transmitter and a light receiver. The light transmitter is used for providing a light energy; the light receiver is used for receiving the light energy to generate high voltage and high power. The gate driver 440 disposed before the photonic isolated power source 410 is used to provide a switch signal to the photonic isolated power source 410, and the photonic isolated power source 410 provides the high voltage and high power to drive the at least one downstream power semiconductor device 490. The at least one power semiconductor device 490 can be a MOSFET or an IGBT. The light receiver of the photonic isolated power source can be a photovoltaic cell as described above. The gate driving module 450 may be packaged in a mounted substrate with a heat sink, such as a cold plate, to achieve heat dissipation. As provided for herein, “mounted substrate” refers to a material structure with good thermal conductivity properties that allow the gate driving module to be mounted to one side, and the heat sink to be mounted to the other side. To improve the heat dissipation rate, high quality thermal interface material(s) can be disposed between the gate driving module 600 and the heat sink. The gate driver 440 is provided with a control signal input 430 and is powered by a power source 420, such as a battery or line power/voltage.

In an alternate configuration of the embodiment of FIG. 4, within the gate driving module 450, the gate driver 440 can be disposed downstream from the photonic isolated power source 410 and be used to receive and switch the high voltage and high power from the photonic isolated power source 410 to drive the at least one power semiconductor device 490. With this configuration, the control signal 430 may be input to the photonic isolated power source 410 or directly provided to the gate driver 410. In this configuration, the power source 420 is not needed, since the photonic isolated power source 410 provides the power and voltage needed by the gate driver to drive the PSD. In still another configuration, the power semiconductor device 490 may be packed with the gate driving module 450 to form a switching power module.

Embodiments where the photonic isolated power supply is shown to drive directly the power semiconductor device, may implement light fidelity (LIFI) techniques to enable faster switching of the power semiconductor device than would be possible by driving the PV cell's output voltage level all the way high and all the way low. Circuitry implementing LIFI techniques may drive (modulate) the output of the light transmitter, as well as interpret the output of the light receiver as a series of on/off signals, which is then used to drive the power semiconductor device. The requisite circuitry is also contemplated as part of this disclosure.

As reference, LIFI is a suite of techniques that vary (modulate) the intensity of a light source (transmitter) such that the output of a light receiver (such as a photo-diode or photovoltaic cell) varies in magnitude as well. Slight changes in the output of the light source intensity are detected by the light receiver, and are interpreted as a change in state (on/off). LIFI can also be used as a means of communication via light, by embedding data signals into the power delivery by modulating the light intensity. The modulated light signal is then detected and processed.

This embodiment, as well as other embodiments, where the photonic isolated power supply 410 is shown to drive directly the power semiconductor device 690, uses the voltage output of the light receiver (for example: a VMJ PV cell) to open (turn on with high voltage) and then close (turn off with low voltage) the gate and therefore drive the power semiconductor device 490. The voltage output of the light receiver is proportional to the output of the light transmitter. Therefore, to achieve the low voltage out of the light receiver required to turn off the gate, the light transmitter should be at sufficiently low intensity. Similarly, for the light receiver to achieve the required voltage level to turn on the gate, the light transmitter must be at a sufficiently high intensity. The speed at which the light receiver can transition between the required on/off voltage levels of the power semiconductor devices gate determines the switching speed of the solution.

By implementing LIFI, additional added circuitry between the photonic isolated power supply 410 and the power semiconductor device 490 can be utilized to detect slight variations (modulations) in the light receiver output (driven by slight changes in the light transmitter output) which correspond to a desired transition from a low to a high state, or vice versa. These detected “transitions” can then drive circuitry that will pull the gate high or low very rapidly, thus decoupling the switching speed from the inherent switching limits from low to high voltage of the light receiver. Furthermore, the light receiver output voltage may be modulated at a voltage level that is always at least the “turn on” voltage of the gate, allowing the output voltage of the light receiver to be used as the voltage source to pull the gate high. Alternatively, an undervoltage-lockout may be included to ensure the output voltage of the light receiver exceeds the minimum required voltage before the light receiver is electrically connected to the gate. Furthermore, in some embodiments, transitions in the light receiver current output (rather than voltage output) may be utilized as a trigger to activate circuitry to drive a gate high, or low. In some light receivers, the current response may be faster than its voltage response, allowing for faster switching via this method.

In other embodiments, LIFI can be used strictly for data communications through the photonic isolated power source, and not as a control signal to turn on, or off the gate. In yet other embodiments, a second light receiver (photovoltaic cell, or photodiode, as examples) that has a faster response time to varying light intensity than the first light receiver that is used to generate the high voltage and high power, can be used to detect fast variations in the light source's output intensity. The detected signal output from this second light receiver can be used to drive the gate on/off, or can instead be used as a means of data communication between the light source and the light receiver. Further embodiments include the use of separate light sources for transmitting power and data (or control) information to the light receiver, or receivers. In those cases, the light source used in the photonic isolated power source to transmit power could provide a continuous output signal, while the light source used for transmitting data or control information would modulate its output. As indicated above, in any embodiment discussed herein, the photonic isolated power source may be disposed before, or after the gate driver, or in some cases may operate independently of a gate driver.

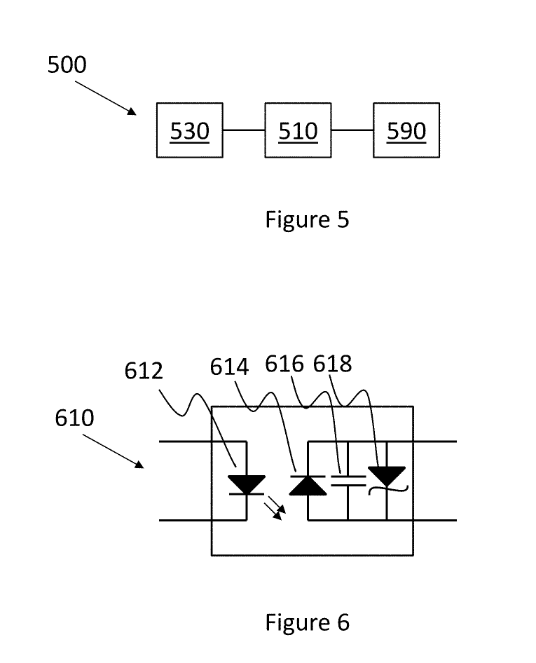

Bi-directional communication across a photonic isolated power source can be achieved by including a light transmitter on the same side of the device as the light receiver (the photovoltaic cell side). This light transmitter would obtain its power from the light receiver, and generate varying optical output to be received by a light receiver (photodiode) located on the same side as the primary light source (LED). FIG. 5 shows yet another embodiment of the present disclosure, illustrating a switching power circuitry diagram 500. In this aspect, a photonic isolated power source 510 is used for driving at least one downstream power semiconductor device 590 such as a MOSFET or an IGBT. As discussed above, the photonic isolated power source 510 can comprise a light transmitter, such as an LED, for providing a light energy, and a light receiver, such as a PV cell, for receiving the light energy to generate a high voltage and high power to drive at least one downstream power semiconductor device 590. A switching power supply 530 is electrically connected to the photonic isolated power source 510 and may be switched by the end user before powering the photonic isolated power source 510. The photonic isolated power source 510 can be packaged in a mounted substrate with a heat sink, such as a cold plate, to achieve heat dissipation. To improve the heat dissipation rate, a thermal interface material can be disposed between the photonic isolated power source 510 and the heat sink. In some embodiments, the photonic isolated power source 510 is packaged with at least one power semiconductor device 590.

In all above embodiments, the light transmitter of the photonic isolated power source may be aligned to the light receiver for ensuring the light energy arriving at the light receiver can be uniform and illuminate the photovoltaic cell across all its junctions 210 (thereby improving performance of VMJ PV cells, since each junction of a VMJ PV cell is connected in series). Waveguides, reflectors, lenses or other optics may be used to direct and alter the light so that it is shaped, sized, and homogenized as desired for optimal performance by the light receiver. The light transmitter, such as laser diode (LD), light emitted diode (LED) and a vertical cavity surface emitting laser (VCSEL) assembly can be used to provide sufficient light energy to the light receiver device. The light from the transmitter may travel through air, through a gas, glass (such as fiber) or through another medium from the light transmitter, to the light receiver. In some embodiments, a waveguide, or other optical component, can be used to create a seal around the light receiver. For this invention, the use of the light receiver contributes a cost and weight reduction because it does not need magnetic cores.

As alluded to above, power semiconductor devices have migrated to higher switching frequencies to improve system efficiencies, resulting in higher steady state power (average power) requirements. Therefore, higher gate “turn on” voltages and gate drive voltages, and higher switching frequencies both result in higher steady state power requirements for the gate driving module. Additionally, the peak power requirement to charge a gate is dependent on its “turn on” speed. A gate is charged so that the voltage at the gate exceeds the required “turn on” voltage and thus, the faster the gate is charged (turned on), the greater its peak power requirement is.

VMJ PV cells, by virtue of their high voltage density (˜3V/mm in width) and high efficiency at converting monochromatic wavelength light to electrical energy at high optical power density, are capable of achieving the voltage density and power density requirements of gate driving applications. The VMJ PV cell can be easily adjusted to different widths, with the width of the cell related to the number of wafers (PN junctions) that are bonded together during fabrication. As an example, a 10 mm wide cell can generate approximately 30V output (when using ˜200 μm wafers in the cell fabrication process), sufficient voltage to exceed the gate “turn on” requirement of any power semiconductor device. With respect to power density, the VMJ PV cell has demonstrated a power density of greater than 25 W/cm² electrical output. Therefore, a 5 mm×3 mm cell (area of 0.15 cm²) could achieve ˜3.75 W electrical output, with a voltage of ˜13V.

To achieve the peak power requirements of power semiconductor gates for switching applications, a capacitor can be incorporated into the photonic isolated power sources discussed above to deliver the peak power requirements for fast gate charging. Furthermore, by mounting to a printed circuit board (PCB) structure, the PV cell can be easily integrated with other key components for a gate driver, enabling the fabrication of a compact integrated circuit package. Finally, the VMJ PV cell has a high reverse voltage breakdown. This makes it highly resistant to electrostatic discharge vents and electrically noisy environments, limiting the need for filtering or special grounding precautions. Such ruggedness can be beneficial for applications desiring compact and/or simplified packaging.

Considering the above, further aspects of the present disclosure relate to additional components of the photonic isolated power sources discussed above, and embodiments for packaging the photonic isolated power sources discussed above. FIG. 6 schematically illustrates another embodiment of a photonic isolated power source 600, comprising a light source (e.g., an LED or laser) 612 and a light detector (e.g., PV cell) 614 to convert the optical light to electricity. A capacitor 616 and Zener diode 618 are further connected in parallel with the light detector 614. In some embodiments a Schottky diode may be used instead of the Zener diode. In still other embodiments, no diode may be used.

Briefly, the capacitor (or capacitors) of the photonic isolated power source provides additional surge power to charge a gate of a power semiconductor device gate, and the Zener diode clamps voltage out of the device at a certain level, to prevent damage to the power semiconductor device gate caused by continued increase of the gate voltage of the power semiconductor device above its damage threshold. As noted above, because power semiconductor devices used in switching applications requires transitioning between ON and OFF states at high frequency, the execution of this transition requires the gate voltage to exceed a certain level to Turn ON, or drop below a certain level to turn OFF. Further, the gate of the power semiconductor device has a gate capacitance that dictates how much it should be charged in order to turn ON the gate. The capacitor helps to rapidly charge the gate to this level to meet the high frequency switching requirements.

The capacitance value of the capacitor is related to how quickly it will discharge, which is therefore related to how fast the device will charge the power semiconductor's gate. In practice, the actual charge rate may be a function of both the gate's capacitance and the internal capacitor's capacitance (although, it is also noted that the gate's resistance can impact the gate's charge); and thus, a capacitor with a capacitance that is much larger than the capacitance of the power semiconductor gate's capacitance may be selected for the photonic isolated power source. In this case, the charge rate is primarily a function of the gate's capacitance.

In short, the capacitor provides extra current to rapidly charge an IBGT's or MOSFET's gate, for switching applications. Once the capacitor is charged, there may be a slight leakage current, but this leakage current is small, compared to the current to charge the gate, to turn it “ON”. It is also noted that the capacitor also allows delivery of an average power from the PV cell instead of a peak power. Sizing the PV cell(s) and LED(s) to meet the average gate charging power instead of the peak gate charging power allows shrinking the size of the PV cell and the LED. This also allows the shrinking of various other elements such as heat sinks, substrates, spacers, and packaging.

To turn OFF the power semiconductor device, its gate is discharged. To allow discharge, power from the PV cell cannot further charge the gate so that the gate can be discharged to ground (e.g., through gate driver circuitry). During the discharge cycle, the above-noted capacitor may still be charged by the PV cell, but may not be discharged to the power semiconductor's gate. As noted above, the charge rate of the capacitor is related to its capacitance, and the discharge rate of the gate is related to the gate's capacitance (and the gate's resistance) and features of the gate driver (including resistance).

When the photonic isolated power source is used in conjunction with the gate driver IC (whether integrated or as separate components), the internal capacitance (of the above-discussed capacitor) may be about five times greater than the gate capacitance of the power semiconductor device. Although this ratio is sufficient to achieve a desired time needed to open the PSD gate (Tr) and time needed to close the PSD gate (Tf), greater ratios improve the signal quality of the voltage at the gate. For a voltage signal that more closely resembles the voltage rise when using a traditional isolated power supply, the capacitor to gate capacitance ratio may be closer to 25 (the capacitor having a capacitance 25 times the gate capacitance). In one specific example, driving a MOSFET with a gate capacitance of 200 pF at 65 KHz, and an internal capacitor capacitance of ˜5 nF (25×) achieved a high-quality voltage level signal at the gate (10V within 20 ns). Alternatively, when the target voltage at the gate is ˜8V, a 1 nF capacitance (5×) ratio may be sufficient to achieve the voltage for Tr and Tf. As shown in the table below, Tr and Tf do not necessarily vary with different capacitor values.

Gate Driving Module tested @ 65 kHz

| | | | | Measured |
|---|---|---|---|---|
| | | | | “Gate On” |
| Gate | Internal | | | Voltage |
| Capacitance | Capacitance | Ratio | Tr/Tf | (Vgate) |
| 200 pF | 1 nF | 5x | <20 ns | 9 V |
| | 4.7 nF | 23.5x | | 10 V |
| | 10 nF | 250x | | 10 V |

Here it is noted that the capacitive value ratio for proper circuit function may vary at different frequencies. Specifically, higher switching frequencies can require more average power to drive the gate. This may require a larger internal capacitor (to store more energy) or increased power out of the photonic isolated power source, or both.

More particularly, as the frequency of switching (ON/OFF cycle) increases, the amount of charge needed to continuously charge the gate of the power semiconductor device so that its voltage exceeds its ON state increases. Further, as switching frequency increases, the time between charges decreases, and therefore the amount of charge delivered by the PV cell to the capacitor in each cycle decreases. Therefore, at faster frequencies, the voltage level (and the charge) of the capacitor will be lower. As a result, at higher frequencies, less charge is delivered to the gate of the power semiconductor device each cycle (assuming the LED output and PV cell output remains the same). Thus, the gate voltage of the power semiconductor device may be a function of the internal capacitance of the photonic isolation power source, the capacitance and resistance of the power semiconductor device, the switching frequency, the PV cell voltage and output power (which is itself based on LED/light source optical power).

In view of this, the LED or LEDs within the photonic isolated power source device may be always on powering the PV cell in order to constantly charge the internal capacitor. Periodically, at a rate determined by the switching frequency, the charge within the capacitor can thus be released to charge the power semiconductor's gate. As the gate is charged, its voltage increases, and eventually exceeds the value required to turn on the gate.

By choosing the appropriate capacitor value, appropriate LED power, and appropriate PV cell, a sufficient power can be available to drive any power semiconductor device at all possible frequencies. To choose an appropriate capacitance, the capacitance should exceed the target power semiconductor device's gate capacitance, as described earlier. These gate capacitances can vary widely, from pF to μF. It is also noted that a capacitance sufficient to power a high gate capacitance power semiconductor device is also sufficient to power a power semiconductor device with a lower capacitance gate. An appropriate Zener diode is chosen based on the voltage output of the PV cell, as well as the voltage damage threshold of the power semiconductor's gate—in other words, one that shuts off at or below the damage threshold of the power semiconductor's gate.

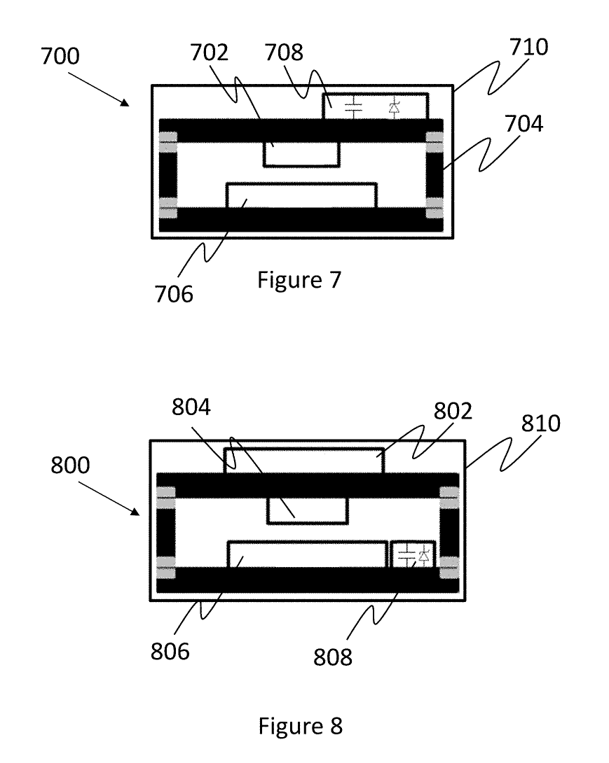

A first packaging embodiment is illustrated in FIG. 7. Conventionally, photocouplers are formed on a lead frame structure to which the PV cell or other light detector is mounted. However, as seen in FIG. 7, the photonic isolated power source package 700 comprises four sections: 1) a light source section (also referred to herein as an LED section) 702; 2) a spacer section 704; 3) a light receiver section (also referred to herein as a cell, PV cell, or VMJ PV cell section) 706; and 4) a capacitor and Zener diode section 708.

As seen in FIG. 7, the middle section represents the spacer section and provides distance (gap) between the LED 702 and the PV cell 706 to achieve voltage isolation. Optical silicone may be used as a filler to partially, substantially completely or completely fill the gap between the LED 702 and the cell 706, to provide higher voltage isolation than achieved with only an air gap. Optical silicone may be applied in the center, on the LED 702, on the PV cell 706, or on some combination, possibly leaving airgaps between any of the spaces. Other materials transparent to the LED 702 or laser wavelength (e.g., having a range of 800 nm to 1064 nm) may also be used, providing alternative voltage isolation levels. For higher voltage isolation levels (e.g., greater than 6 kV) having greater distances, lenses, waveguides or light pipes may be used to focus the light onto the PV cell 706, and/or to increase the uniformity of light over the PV cells 706. In other words, the spacer section 704 can be modified (e.g., in height, insulating material, and the like) to customize the package 700 to a desired voltage isolation level without changing the light source section 702 or the light receiver section 706.

The light source section 702 may have any number of light sources (e.g., 2 or more LEDs). However, an alternative number of LEDs or light sources may be utilized (mounted) on the same substrate section. As an example, 4 LEDs 702 may be utilized to either provide light to one or more PV cells 706, or to create a more uniform illumination of light over the PV cell(s) 706. A greater number of LEDs 702 may provide greater uniformity, due to overlapping beam profiles, which is key to the optimum performance of the PV cell. In addition to increasing voltage isolation, increasing the distance between the LED(s) 702 and the PV cell(s) 706 may also increase beam uniformity. Increasing the number of LEDs 702 may be accomplished by selecting smaller LEDs, or by duplicating a submount of LEDs (e.g., where each submount includes 2 LEDs). In the case of duplicating the submount, increasing the beam profile width by two allows for increasing the width of a VMJ PV cell by two, resulting in a doubling of the output voltage.

For LIFI implementation (as discussed above, a method of sending data via varying light intensity), one LED may be always on, ensuring that the PV cell always achieves a minimum voltage, while a second LED's power output may be dynamically adjusted. This provides a variation in power out of the PV cell to indicate data transmission.

When fully packaged, the photonic isolation power source devices have top source section 702 having the capacitor and Zener diode section 708 attached, and a case 710 enclosing the entire package. Alternatively, the capacitor and Zener diode section may be mounted to the same substrate as the PV cell section. A black epoxy may be applied to the outside of the packaging to provide the appearance of a case, and covering any components such as the capacitor and Zener diode.

A second embodiment of packaging 800, shown in FIG. 8, incorporates a gate driver integrated circuit (IC) 802 with the photonic isolated power source (having light source section 804 and light receiver section 806), resulting in an optically isolated gate driving module (also called the gate driving module, gate driver module, or optically isolated gate driver) 800. The structure of the photonic isolated power source can be the same as the photonic isolated power source 700 shown above in FIG. 7, and can further include the capacitor and Zener diode section 808 mounted on the same substrate as the light receiver section 806. In addition, the gate driver IC 802 is mounted to the top of the light source section 804, however in other embodiments, the gate driver IC 802 may be contained inside the photonic isolated power source structure and mounted on a PCB. As above, a case 810 may enclose all or a portion of the elements of the optically isolated gate driver 800.

In other embodiments, the gate driver IC 802 may be mounted directly to a PCB with the light detector (the light receiver section 806), or the PCB with the light source (the light source section 804). Since the gate driver IC 802 has both a low side, and high side voltage, when mounted to a PV cell 806, the low side voltage is separated from high side components at a distance that exceeds the gap distance between the LED 804 and the PV cell 806 (minimum gap). When the gate driver IC 802 is mounted to the LED substrate 804, the high side voltage of the gate driver IC 802 is separated from the low side components at a distance that exceeds the gap distance between the LED 804 and the PV cell 806. The minimum distance between the gate driver IC 808 and other components may be adjusted, depending on the actual material used to fill the gap between the PV cell 806 and the LED 804.

It is also noted that in some embodiments, a gate driver die may be integrated instead of the packaged gate driver IC. A gate driver die may be easier to mount to the same PCB as either the PV cell or the LED, further shrinking the overall size of the device.

Each of the above described sections may be formed from a PCB with any components thereon mounted on either side of the PCB (or on two PCBs facing each other). Mounting the light source on one PCB and the light receiver on a second PCB facing the first allows for precise alignment, which helps improve performance of PV cells, when using VMJ PV cells, which perform optimally with uniform light that illuminates all the junctions. This configuration also allows for easy insertion of an isolation medium between the two PCBs. Mounting on opposing sides of a PCB facilitates integration of additional circuitry and components within a smaller package. For example, the components of the package 700 or 800 may be mounted directly to a PCB or other ceramic substrate (such as HTCC or LTCC), thereby allowing high volume production and low-cost fabrication. Such mounting may comprise printing trace patterns onto the PCB, placing the components on the PCB, heating the PCB, placing a PV cell 706 and bonding the PV cell 706 onto the PCB, and finally attaching leads to the PV cell 706 via an epoxy (e.g., silver epoxy, surface mount tin epoxy, or the like). In other embodiments, the PV cell 706 may be bonded prior to placing and bonding other components.

When the light receiver section 706, 806 is embodied as a VMJ PV cell, it is not possible to simply mount the cell to a conducting lead (or leg) of a conventional lead frame package used for photocouplers. This is because the VMJ PV cell has multiple vertical PN junctions, such that a traditional metal frame conducting lead would short the cell. Further, wire bonding the cell to a metal frame is difficult due to the rough surface of the cell. Finally, precise alignment of components mounted on metal frame leads is difficult. These issues can be overcome by mounting the cell on a PCB as described above, in which the cell's leads can be electrically connected to the appropriate circuit traces/leads via the silver epoxy, surface mount tin epoxy, or the like.

An alternative device construction of package 700 or 800 includes all low side components on one PCB, and all the high side components on the other PCB. Such a configuration can achieve higher voltage isolation photonic isolated power sources, or a higher voltage isolation optically isolated gate drivers. For a standalone photonic isolated power source, the LED can be mounted on one PCB, while the PV cell, Zener diode, and capacitor can be mounted to the other PCB.

For the construction of an optically isolated gate driver, in one embodiment, an LED (the light source) is mounted to the low side PCB for transmitting optical power to the light receiver (PV cell) on the high side. An additional optical transmitter (which can be a low power LED) for transmitting control signals optically to the high side PCB can also be mounted on the low side PCB. The high side PCB then has the PV cell, Zener diode, and capacitor mounted thereon. In addition, a non-isolated gate driver IC is mounted to the high side PCB. To operate the gate driver, photodiodes also mounted on the high side PCB detect the low power LED optical control signals, and these signals serve as the input to the gate driver control signal inputs. Finally, the voltage and power required by the non-isolated gate driver IC is supplied as previously described by the photonic isolated power supply. The benefit of this architecture is that it allows for an isolated gate driver construction that can achieve many different isolation levels (not limited by the rated voltage isolation levels of existing gate driver ICs), and very high isolation levels, where the isolation level is determined solely by the isolation obtained due to insulation between the light source (LED) and the light receiver (PV cell).

It is also noted that any of the above-described package architectures can be fabricated with output legs/pins or with solder pads.

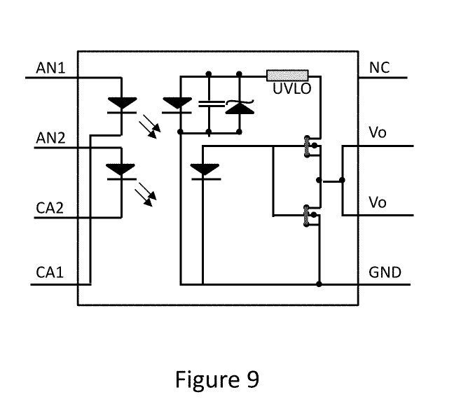

FIG. 9 illustrates an example electrical schematic integration of a gate driver with a photonic isolated power source, when in the same package. The PV cell, the capacitor, and Zener diode are shown within the circuitry, all in parallel, using their conventional symbols. Additionally, an undervoltage lockout circuit is shown at the output of the photonic isolated power source. Additional circuitry includes a second LED light source is shown illuminating a second photosensitive device, which is connected to the gates of the two MOSFETs. This additional circuitry represents the signaling circuitry of a traditional integrated photocoupler-gate driver IC. In this manner, the output of the photonic isolated power source powers the MOSFETs while the output of the second photocoupler controls operation of the MOSFETs at their gates. While FIG. 9 shows an optically isolated control signal, other embodiments may achieve control signal voltage isolation alternatively, such as via RF signaling from a transmitter to a receiver.

As noted above, the PV cell may include a plurality of contacts between different PN junctions to produce alternative voltage outputs. In these cases, the zero (or ground) voltage comes from the metal contact in the middle of the cell, while Vo (the gate voltage) switches from +Vo (a positive voltage contact) to −Vo (a negative voltage contact) such that Vo is the absolute value of the positive and negative sides of the multi-voltage VMJ PV cell output. With this configuration, Vo can be connected to the gate of the power semiconductor device and the gate of the power semiconductor device may discharge in a manner that recharges the internal capacitor. This can provide faster charging of the capacitor, and reduced power requirements from the PV cell. Here, the capacitor may be connected between the ground contact and either the positive or negative contact of the PV cell, or between the positive and negative contacts of the PV cell. Furthermore, the plurality of metal contacts, and the PN junctions on alternative sides of the metal junctions may be configured such that the output voltages from the VMJ PV cell are asymmetric, such as +20V/−4V, or +15V/−5V, or +6V/−3V. The negative output possible with the VMJ PV cell allows for applying a negative voltage across the PSD's gate, allowing for more rapid switching.

According to another aspect of the present disclosure, the above described photonic isolated power sources (and integrated gate drivers) can be used with integrated power module (IPM, also referred to as an intelligent power module, smart power module, and switching power module) applications. IPMs combine multiple gate driver components (e.g., the gate driver IC described above) and downstream power semiconductor devices (e.g., IGBTs and MOSFETs) not part of the gate driver or photonic isolated power source, in order to provide a compact, efficient package containing high voltage (HV) control from HV-DC to 3-phase outputs in a single small SIP module. The output stage can use IGBT/FRD technology and implement under voltage protection and over current protection with a fault detection output flag. Internal boost diodes may be provided for high side gate boost drive. Such IPMs can be used, for example, to drive three phase motors for various applications (with 2 downstream IGBTs per phase).

To operate IPMs, multiple photonic isolated power sources (or gate driving modules when packaged in combination with gate driver ICs) can be integrated in a common package with the IPM power semiconductor devices. In various embodiments, different components (such as the Zener diode and capacitor, when included) can be housed external to the integrated photonic isolated power source and IMP package.

According to various embodiments, IPMs power semiconductor devices integrated with photonic isolated power sources and gate drivers may have different configurations. In a first example, a single gate driving module is provided for all HV side power semiconductor devices, and a single gate driving module is provided for all low-voltage side power semiconductors. In a second example, a single gate driving module is provided for two power semiconductor devices of a common phase (one power semiconductor device for each of the high voltage and low voltage side of that phase). In a third example, individual gate driving modules are provided for each HV side power semiconductor device, and a single gate driving module is provided for all low voltage side power semiconductor devices. In each of these examples, the gate driving module comprises the photonic isolated power source and gate driver IC as discussed above, and is packaged together with the power semiconductor devices of each phase.

The description is given here to enable those of ordinary skill in the art to practice the invention. Many configurations are possible using the instant teachings, and the configurations and arrangements given here are only illustrative. Those with ordinary skill in the art will, based on these teachings, be able to modify the invention as shown. The invention as disclosed using the above examples may be practiced using only some of the optional features mentioned above. Also, nothing as taught and claimed here shall preclude addition of other reflective structures or optical elements. Obviously, many modifications and variations of the present invention are possible in light of the above teaching. It is therefore to be understood that, within the scope of the appended claims, the invention may be practiced otherwise than as specifically described or suggested here.

What is claimed is:

1. An integrated power source comprising:
a first printed circuit board (PCB);
a second PCB;
a photonic isolated power source comprising:
a light transmitter surface mounted on a first side of the first PCB; and
a multijunction photovoltaic (PV) cell surface mounted on a first side of the second PCB and configured to detect light emitted by the light transmitter;
a gate driver circuit; and
a housing enclosing the first PCB, the second PCB, and the photonic isolated power source,
wherein the first side of the first PCB and the first side of the second PCB face each other, and
wherein an output of the photonic isolated power source and the gate driver circuit are configured to supply power to and drive at least one downstream power semiconductor.

2. The integrated power source of claim 1, wherein the gate driver circuit is enclosed within the housing.

3. The integrated power source of claim 1, wherein the at least one downstream power semiconductor is a metal-oxide-semiconductor field effect transistor or an insulated gate bipolar transistor.

4. The integrated power source of claim 1, wherein the multijunction PV cell is a vertical multijunction (VMJ) PV cell.

5. The integrated power source of claim 1, wherein the light emitter and the PV cell are separated by a gap.

6. The integrated power source of claim 5, wherein optical silicone at least partially fills the gap.

7. The integrated power source of claim 1, further comprising a heat sink on which the housing is mounted.

8. The integrated power source of claim 1, wherein the photonic isolated power source or the gate driver circuit is supplied by a switching power supply.

9. The integrated power source of claim 1, wherein an output of the gate driver circuit is supplied to the photonic isolated power source and configured to switch the photonic isolated power source.

10. The integrated power source of claim 1, wherein an output of the photonic isolated power source is supplied to the gate driver circuit, the gate driver circuit being configured to switch a supply of power from the photonic isolated power source to and drive the at least one downstream power semiconductor.

11. The integrated power source of claim 1, further comprising a capacitor and/or a Zener or Schottky diode connected in parallel with the PV cell.

12. The integrated power source of claim 11, wherein the capacitor and/or the Zener or Schottky diode is mounted to a second side of the first PCB.

13. The integrated power source of claim 11, wherein the capacitor and/or the Zener or Schottky diode is mounted to the first side of the second PCB.

14. An intelligent power module comprising:
at least one integrated power source of claim 1; and
at least one downstream power semiconductor,
wherein an output of the integrated power source is configured to supply power to and drive the at least one downstream power semiconductor, and
wherein the housing further encloses the at least own downstream power semiconductor.

15. The intelligent power module of claim 14, wherein:
the at least one integrated power source of claim 1 includes a high voltage integrated power source and a low voltage integrated power source,
the at least one downstream power semiconductor includes a high voltage downstream power semiconductor and a low voltage downstream power semiconductor,
the high voltage integrated power source is configured to supply power to and drive the high voltage downstream power semiconductor, and
the low voltage integrated power source is configured to supply power to and drive the low voltage downstream power semiconductor.

16. The intelligent power module of claim 14, wherein:
the at least one integrated power source of claim 1 includes a first integrated power source,
the at least one downstream power semiconductor includes a high voltage downstream power semiconductor and a low voltage downstream power semiconductor, the high voltage downstream power semiconductor and the low voltage downstream power semiconductor operating at a common phase, and
the first integrated power source is configured to supply power to and drive the high voltage downstream power semiconductor and the low voltage downstream power semiconductor.

17. The intelligent power module of claim 14, wherein:
the at least one integrated power source of claim 1 includes a first high voltage integrated power source, a second high voltage integrated power source, and a low voltage integrated power source,
the at least one downstream power semiconductor includes first and second high voltage downstream power semiconductors and first and second low voltage downstream power semiconductor,
the first high voltage integrated power source is configured to supply power to and drive the first high voltage downstream power semiconductor,
the second high voltage integrated power source is configured to supply power to and drive the second high voltage downstream power semiconductor, and
the low voltage integrated power source is configured to supply power to and drive the first and second low voltage downstream power semiconductors.

18. An integrated power source comprising:
a first printed circuit board (PCB);
a second PCB;
a photonic isolated power source comprising:
a light transmitter surface mounted on a first side of the first PCB; and
a multijunction photovoltaic (PV) cell surface mounted on a first side of the second PCB and configured to detect light emitted by the light transmitter;
a gate driver circuit; and
a housing enclosing the first PCB, the second PCB, the photonic isolated power source, and the gate driver circuit,
wherein the first side of the first PCB and the first side of the second PCB face each other and the light emitter and the PV cell are separated by a gap, and
wherein an output of the photonic isolated power source and the gate driver circuit are configured to supply power to and drive at least one downstream power semiconductor.
